(19) United States
(12) Patent Application Publication
(10) Pub. No.: US 2009/0221152 A1
(43) Pub. Date: Sep. 3, 2009

(54) Etching Solution And Method For Structuring A UBM Layer System

(76) Inventors: Frank Dietz, Itzehoe (DE); Klaus Kohlmann-Von Platen, Itzehoe (DE); Hans-Joachim Quenzer, Itzehoe (DE)

Correspondence Address: GREENBLUM & BERNSTEIN, P.L.C., 1950 ROLAND CLARKE PLACE, RESTON, VA, 20191, US

(21) Appl. No.: 12/280,293

(22) PCT Filed: Feb. 16, 2007
(86) PCT No.: PCT/EP07/01363

§ 371 Date: Dec. 16, 2008

(30) Foreign Application Priority Data
Feb. 22, 2006 (DE) 10 2006 008 261.3

(51) Int. Cl. H01L 21/461; C09K 13/04; C09K 13/06; B44C 1/22

(52) U.S. Cl. 438/754; 252/79.2; 252/79.4; 216/41; 257/E21.219

(57) ABSTRACT

Etching solution for etching a layer system that has at least one layer of aluminum, at least one layer of copper and at least one third layer, selected from nickel vanadium, nickel and alloys thereof, which is arranged between the at least one aluminum layer and the at least one copper layer, wherein the solution contains phosphoric acid, nitric acid, deionized water and at least one salt that can release halogen ions, or comprises these components. The claimed etching solution is the basis for a one-step structuring method of a UBM layer system which is used in the production of components that are produced by semiconductor technology methods.

### TECHNICAL FIELD

In order to render possible an interface of a semiconductor chip with the outside world or another external structure, special contact surfaces (Under Bump Metallization=UBM) are necessary. The invention relates to an etching solution and a method with which a UBM layer system of this type can be structured in the simplest manner possible.

### PRIOR ART

A UBM layer system represents a special sequence of different conductive layers in contact with one another, and is designed to ensure the best and most durable possible contact between a substrate, for example, a wafer, and a bonding material, for example, a solder, or the external structure connected thereto, for example, a wire or a second substrate.

UBM layer systems are becoming increasingly important, particularly with the development of the flip chip technology.

A UBM layer system is intended to bring about an optimal electrical as well as mechanical contact. Moreover, the contact must render possible the dissipation of thermal energy with various applications, without significantly changing its properties. In order to meet these conditions, the materials used in a UBM layer system should generally have a good adhesion to the respective base, as a rule aluminum and/or silicon nitride and/or silicon oxide on the one hand, and a good wettability with respect to the bonding material used, often a solder containing tin, on the other hand. Furthermore, the entire layer sequence should have a high conductivity.

When taking these requirements into account, a combination of copper, nickel vanadium and aluminum has proven to be particularly suitable. The aluminum layer thereby produces the connection to the generally top metal layer of the wafer, usually likewise aluminum. The nickel vanadium layer applied to the aluminum serves as a diffusion barrier and prevents metal atoms from the copper layer arranged thereon and the bonding material lying above from migrating through the aluminum layer into the substrate and contaminating or influencing doped areas. The final copper layer guarantees a low contact resistance and a good connection to the bonding material.

In order to be able to meet these technological requirements for a structured UBM layer system, comprising a copper layer, a nickel vanadium layer and an aluminum layer, the metal layers are usually structured individually or two metal layers are structured at the same time.

Nitric acid is generally used as the standard etching solution for copper. According to U.S. Pat. No. 6,130,141, however, iron chloride or mixtures of sulfuric acid and potassium chromate or sulfuric acid and peroxide can also be used for the copper etching.

A commercially available solution for nickel etching contains thiourea, which is considered carcinogenic and thus involves a high risk potential.

Another etching solution for nickel vanadium is disclosed in WO 8904883. A highly concentrated iron (III) chloride solution is used thereby, which, however, is not clean-room compatible and is unsuitable for use in semiconductor production.

Another etching method for structuring a nickel vanadium layer is known from US20030146191. The nickel vanadium layer is thereby etched electrochemically using sulfuric acid.

A concentrated phosphoric acid solution is generally used for etching the aluminum layer (Kirt R. Williams, Kishan Gupta, Matthew Wasilik, “Etch Rates for Micromachining Processing—Part II,” Journal of Microelectromechanical Systems, Vol. 12, No. 6, December 2003).

A method in which all three layers are structured simultaneously is described in DE 695 12 991. The etching solution used thereby comprises phosphoric acid, deionized water, acetic acid and hydrogen peroxide. This solution has the disadvantage that hydrogen peroxide is a highly reactive medium that requires a correspondingly high expenditure in terms of safety measures with respect to storage and transportation. Furthermore, under atmospheric conditions hydrogen peroxide breaks down relatively quickly into water and hydrogen, which leads to a change in the concentration of the etching solution. The change in the etching rate thereby entailed influences the quality of the UBM layer system and impedes a controlled etching process.

### Specification

The object of the invention is to overcome the disadvantages of the prior art and to disclose an etching solution and a method with which a layer system according to the preamble of the main claim can be structured under clean-room conditions and taking into account the processes of semiconductor technology in the fewest possible steps and the process step of structuring takes place effectively and in a controllable manner.

According to the present invention, the object is attained by an etching solution according to claim 1. Claim 21 discloses a method for structuring a layer system according to the preamble of the main claim.

The subordinate claims teach advantageous further developments of the invention; claims 38 through 46 disclose advantageous uses.

The etching solution according to the invention is suitable for etching a layer system that has at least one layer of aluminum, at least one layer of copper and at least one third layer, selected from nickel vanadium, nickel and alloys thereof, which is arranged between the at least one aluminum layer and the at least one copper layer. The etching solution contains or comprises phosphoric acid, nitric acid, deionized water and at least one salt that can release halogen ions, in particular under the conditions of the etching method according to the invention.

One advantage of the etching solution according to the invention lies in the fact that a copper/nickel vanadium/aluminum layer system can be structured in one process step. A contamination of the layer system is reduced through the reduced number of process steps compared to 2-step and 3-step etching methods. The etching solution according to the invention furthermore has the advantage that possibly contaminating chemical compounds, such as, for example, KOH, sodium compounds or ammonium compounds can be omitted. Furthermore, the etching solution does not contain any highly reactive and carcinogenic media, which reduces the expenditure for necessary safety measures. Another advantageous factor is the comparatively low consumption of material, which ensures a more effective use of the etching process. Another advantage to be emphasized is that the etching solution does not need to be activated even after not having been used for days and is therefore immediately ready for use.

The etching solution according to the invention contains as a halogen component a salt releasing halogen ions. In combination with the acids contained in the etching solution and the copper layer applied thereto the attack on the nickel vanadium layer is thereby rendered possible. The salt releasing halogen ions is preferably a metal salt, the anions of which are halogen ions. The cations of the metal salt are particularly preferably chosen from the metals contained in the layer system. Additional metals that are not contained in the layer system can thereby be prevented from affecting the etching process and the quality of the structured layer system. A particularly suitable metal salt is aluminum chloride.

The halogen component or the salt releasing halogen ions should preferably ensure the release of halogen ions even under acid conditions with a pH value between approx. 0 and approx. 3, the particularly preferable range being between a pH value of approx. 1 and approx. 2.

In a preferred embodiment, the etching solution contains 30-45% by volume phosphoric acid, 5-10% by volume nitric acid, 45-55% by volume deionized water and at least 0.1 mol/l halogen component.

In a further preferred embodiment, the etching solution contains a complex-forming ligand that is stable at a pH value of less than equal to 3, particularly preferably also at a pH value of less than equal to 1, and forms stable complexes with copper ions under the respective in particular acid conditions. According to the invention, stable complexes mean complexes with a complex formation constant of pK>5. In particular in the structuring of a layer system that comprises materials that form galvanic cells, there is a risk that the depositing and growth of metal ions will occur. The risk is particularly high with the simultaneous structuring of several layers. Depositions of metal ions, such as, for example, copper ions, can be reduced by a suitable complexing agent.

Ligands that are at least 3-dentate, preferably 6-8-dentate and contain amine groups and/or carboxylic acid groups are particularly suitable, the amine groups preferably being tertiary amines.

As a particularly preferred complex-forming ligand, the etching solution contains EDTA or another ligand that forms complexes with copper, the complex formation constant of which is pK>10, preferably pK>16. EDTA forms particularly strong complexes with copper ions and other metal ions.

The aim is for the highest possible proportion of complex-forming ligands in the solution, wherein no precipitation may occur. The maximum concentration of complex-forming ligands is therefore limited by the limit of solubility and, for example, with EDTA, lies below 3% by volume of the total solution.

According to the invention, the etching solution can contain organic acids (such as, for example, phenol, acetoacetic ester, acetic acid) preferably carboxylic acids, particularly preferably carboxylic acids with at least two carboxylic acid groups. In a particularly preferred embodiment, the carboxylic acid has one or more hydroxy groups. Preferably, at least one hydroxy group is arranged vicinally or geminally to one of the carboxylic acid groups. Surprisingly, these organic acids have the advantage that they act as inhibitor to prevent crystalline growth, in particular the growth of copper crystallites.

Citric acid and tartaric acid are particularly suitable inhibitors. The highest possible inhibitor concentration is desired in the solution, wherein a precipitation should likewise be avoided. The maximum concentration is limited by the limit of solubility and with citric acid, for example, lies below 5% by volume of the total solution.

The method according to the invention for structuring a layer system, which at least one layer of aluminum, at least one layer of copper and at least one third layer, selected from nickel vanadium, nickel and alloys thereof, that is arranged between the at least one aluminum layer and the at least one copper layer, has the following process steps:
Provision of a substrate, on which the layer system (2, 3, 1) is arranged or applied
Arrangement or production of an etching mask on the surface of the layer system, wherein the etching mask covers the at least one copper layer at least in part
Etching step, in which at least two layers of the layer system are etched with an etching solution that contains phosphoric acid, nitric acid, deionized water and at least one halogen component that can release halogen ions, or comprises these components
Rinsing step, in which the etched layer system is rinsed with water and/or a base
Drying of the etched layer system
Removal of the etching mask.

The UBM layer system to be structured with the claimed method, which layer system is arranged or applied on a substrate, for example, a wafer, has at least one layer of nickel vanadium or nickel or alloys thereof. Preferably nickel vanadium is used, wherein the vanadium proportion is, for example, approx. 7%. Through the introduction of vanadium, a diamagnetic nickel vanadium alloy is formed from the ferromagnetic nickel, which is important in particular for the process of the layer deposition by means of magnetron sputtering. Typically a nickel vanadium layer with a thickness in the nm range or in the μm range is applied, wherein a minimum thickness is predetermined through the desired properties of the nickel vanadium layer acting as diffusion barrier. The thickness of the copper layer and of the aluminum layer is usually likewise in the nm range or in the μm range. The layer thicknesses are generally selected such that the mechanical stresses between the layers and the stress gradients in the layers are as low as possible in order to avoid a sagging of the wafer or a chipping off of layers.

In order to be able to achieve optimal results as far as possible, the composition of the etching solution and thus the etching rate of the various materials must be adjusted according to the ratio of the individual layer thicknesses.

In a first process step usually a photoresist layer is applied to the surface of the copper layer, which covers the areas not to be etched and protects them from attack by the etching solution. Other materials in addition to various photoresists can also be used for an “etching mask” of this type. Materials for the etching mask should in principle have a good adhesion to the copper layer in order to prevent a penetration of the etching solution under the etching mask and an associated detachment or pronounced undercutting of the etching mask. Furthermore, the etching mask should be resistant with respect to the etching solution in order to protect the covered areas from attack by the etching solution during the entire duration of the etching step. In general, the lowest possible undercutting is desirable in order to guarantee the largest possible contact surface and thus a stable mechanical connection. Furthermore, pronounced undercutting can lead to an attack of the layer under the UBM stack, which would increase the electrical resistance of the contact surface and reduce the stability of the mechanical connection of the UBM stack to the substrate.

The uncovered areas are structured in a subsequent etching step (etching process), wherein the advantage of the method according to the invention lies in particular in that all three metal layers (copper, nickel vanadium, aluminum) are removed in one process step and the technical requirements for the etched layer system are met.

The etching process preferably takes place in a commercially available wet etching basin, wherein up to 25 wafers can be etched simultaneously. With an etching yield of at least 15 wafers per liter etching solution, more than 300 wafers can be structured with a wet etching basin filling of 20 liters. This is made possible by the relatively low consumption of material of the etching process. Furthermore, the method according to the invention is also suitable for use in sputter etching processes.

An optimal control of the etching process is promoted by the layer system being in contact with the etching solution for at least 1 minute.

The etching rates of the individual metal layers depend on the temperature, among other things. The etching step is carried out at temperatures between approx. 15° C. and 80° C., preferably between approx. 35° C. and 60° C. Under these conditions, copper is removed only slightly in the areas covered by the etching mask, whereby the etching mask is undercut only slightly. The copper layer in turn is undercut only slightly by the removal of the nickel vanadium layer. An undercutting of the nickel vanadium layer by the aluminum removal does not occur. Even if the optimal etching duration is exceeded by up to 10%, the nickel vanadium layer is generally not undercut by the aluminum removal. As a rule, with increasing temperature, the etching rate of aluminum increases and the etching rate of copper is reduced. Variations thus occur in the strength of the undercutting. It is therefore necessary for the temperature as well as the mixture ratio of the etching solution to be coordinated with the layer system to be etched.

Preferably the etching solution that contains phosphoric acid, nitric acid, deionized water and at least one halogen component that can release halogen ions, or comprises these components is used in semiconductor production and/or in the manufacture of components that are produced by means of semiconductor technologies, in particular for etching a layer system that has at least one layer of aluminum, at least one layer of copper and at least one third layer, selected from nickel vanadium, nickel and alloys thereof that is arranged between the at least one aluminum layer and the at least one copper layer and particularly preferably represents a UBM stack.

The invention is described in more detail below based on diagrammatic drawings and an exemplary embodiment.

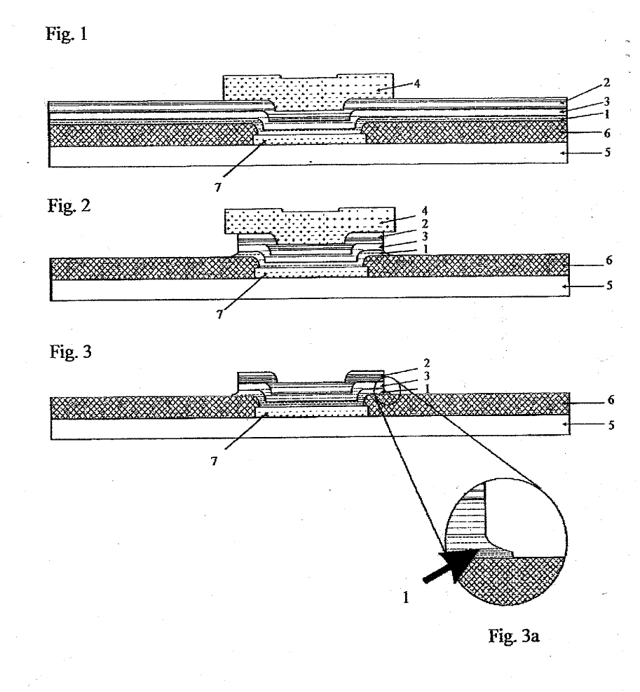

FIG. 1 shows a layer system (2, 3, 1) arranged on a substrate (5), for example, a wafer, comprising an aluminum layer (1), a nickel vanadium layer (3) and a copper layer (2) and a photoresist layer as an etching mask (4).

FIG. 2 shows the finished structured layer system (2, 3, 1) with photoresist layer as an etching mask (4).

FIG. 3 shows the finished structured layer system (2, 3, 1) after removal of the photoresist layer as an etching mask (4).

FIG. 3a shows the aluminum layer (1) projecting under the copper layer (2) and the nickel vanadium layer (3).

FIG. 1 shows an unstructured layer system (2, 3, 1) arranged on a substrate (5), comprising an aluminum layer (1) approx. 0.5 μm thick, a nickel vanadium layer (3) approx. 0.5 μm thick and a copper layer (2) approx. 1 μm thick. The passivation layer (6) arranged between the substrate (5) and the lowest layer of the layer system, the aluminum layer (1), is used for electrical insulation. An AZ photoresist layer (4) is applied on the copper layer (2) as an etching mask and structured in order to protect the areas of the layer system (2, 3, 1) not to be etched from the etching attack.

Good results can be achieved with an etching solution of 37.4% by volume phosphoric acid, 7.4% by volume nitric acid, 51.6% by volume deionized water, 0.36% by volume aluminum chloride, 0.8% by volume EDTA and 2.4% by volume citric acid. The etching process is carried out at temperatures between 45° C. and 47° C.

The result of the etching step is shown in FIG. 2. The layer system (2, 3, 1) is removed in the areas not covered by the etching mask (4) and the etching mask (4) is undercut only slightly.

Through undercutting the copper layer (2) recedes by a maximum of 8 μm under the etching mask (4). A receding of the nickel vanadium layer (3) with respect to the copper layer (2) and a receding of the aluminum layer (1) under the nickel vanadium layer (3) by undercutting do not usually occur.

After the etched layer system (2, 3, 1) has been rinsed with water for approx. 10 minutes and subsequently dried for approx. 10-12 minutes in a rinse dryer that is customary in the semiconductor industry, the photoresist layer (4) acting as an etching mask is removed (FIG. 3). In a subsequent monitoring the quality of the etching process is inspected. Particular attention is paid thereby to the aluminum layer (1). The aluminum layer (1) should visibly project under the copper layer (2) and the nickel vanadium layer (3) in order to rule out an undercutting or a removal of the metal layer under the UBM stack (7).

### LIST OF REFERENCE NUMBERS

1 Aluminum layer
2 Copper layer
3 Nickel vanadium layer
4 Etching mask of photoresist
5 Substrate
6 Passivation layer
7 Metal layer under the UBM stack, e.g., chip metallization

1-46. (canceled)

47. Etching solution for etching a layer system comprising phosphoric acid, nitric acid, deionized water and at least one salt that can release halogen ions and cations of which are selected from aluminum, nickel, and vanadium.

48. Etching solution according to claim 47, wherein the at least one salt comprises aluminum chloride.

49. Etching solution according to claim 47, comprising 30-45% by volume phosphoric acid, 5-10% by volume nitric acid, 45-55% by volume deionized water and at least 0.1 mol/l aluminum chloride.

50. Etching solution according to claim 47, further including a complex-forming ligand that is stable at pH≦3 and can form complexes with Cu ions under these conditions.

51. Etching solution according to claim 50, wherein the complex-forming ligand is EDTA.

52. Etching solution according to claim 51, containing less than 3% by volume EDTA.

53. Etching solution according to claim 47, further containing an organic acid.

54. Etching solution according to claim 53, wherein the organic acid is citric acid and/or tartaric acid.

55. Etching solution according to claim 54, containing less than 5% by volume citric acid.

56. Method for structuring a layer system that includes at least one layer of aluminum, at least one layer of copper and at least one third layer arranged between the at least one aluminum layer and the at least one copper layer, the at least one third layer being selected from nickel vanadium, nickel and alloys thereof, comprising the following:
providing a substrate with the layer system including at least one layer of aluminum, at least one layer of copper and at least one third layer arranged between the at least one aluminum layer and the at least one copper layer, the at least one third layer being selected from nickel vanadium, nickel and alloys thereof;
arranging or producing an etching mask on a surface of the layer system so that the etching mask covers the at least one copper layer at least in part;
etching at least two layers of the layer system with an etching solution containing phosphoric acid, nitric acid, deionized water and at least one halogen component that can release halogen ions, or comprising halogen ions;
rinsing the etched layer system with water and/or a base;
drying the etched layer system; and
removing the etching mask.

57. Method according to claim 56, wherein the etching solution contains as the at least one halogen component at least one salt that can release halogen ions and the salt including at least one of aluminum, nickel, vanadium, and copper as a cation.

58. Method according to claim 57, wherein the etching solution comprises phosphoric acid, nitric acid, deionized water and as the at least one halogen component at least one salt that can release halogen ions and the at least one salt including at least one of aluminum, nickel, or vanadium as a cation.

59. (canceled)

60. Method according to claim 56, comprising etching at least the copper layer, the aluminum layer and the at least third layer.

61. A method of etching a layer system that includes at least one layer of aluminum, at least one layer of copper and at least one third layer which is arranged between the at least one aluminum layer and the at least one copper layer, the at least one third layer being selected from nickel vanadium, nickel and alloys thereof, comprising etching the layer system with an etching solution containing phosphoric acid, nitric acid, deionized water and at least one halogen component, and the at least one halogen component comprising at least one salt that can release halogen ions, or comprising halogen ions.

62. The method according to claim 61, wherein the etching solution contains as the at least one halogen component at least one salt that can release halogen ions and the at least one salt including at least one of aluminum, nickel, vanadium, and copper as a cation.

63. The method according to claim 61, wherein the etching solution comprises phosphoric acid, nitric acid, deionized water and as the at least one halogen component at least one salt that can release halogen ions and the at least one salt including at least one of aluminum, nickel, and vanadium as a cation.

64. (canceled)

65. The method according to claim 61 wherein the etching a layer system comprises etching a UBM stack.

66. The method according to claim 61, wherein the etching a layer system comprises etching a layer system during semiconductor production.

67. The method according to claim 61, wherein the etching a layer system comprises etching a layer system of a component produced from semiconductor technology.

68. Etching solution according to claim 50, wherein the complex-forming ligand is stable at pH≦1.
